(19) United States
(12) Patent Application Publication
(10) Pub. No.: US 2018/0270942 A1
(43) Pub. Date: Sep. 20, 2018

(54) HIGH-FREQUENCY CIRCUIT

(71) Applicant: KABUSHIKI KAISHA TOSHIBA, Tokyo (JP)

(72) Inventors: Tamio KAWAGUCHI, Kawasaki Kanagawa (JP); Hiroaki IKEUCHI, Yokohama Kanagawa (JP); Noritsugu SHIOKAWA, Yokohama Kanagawa (JP)

(73) Assignee: KABUSHIKI KAISHA TOSHIBA, Tokyo (JP)

(21) Appl. No.: 15/691,415

(22) Filed: Aug. 30, 2017

(30) Foreign Application Priority Data
Mar. 17, 2017 (JP) 2017-053117

(51) Int. Cl. H05K 1/02; H05K 1/18; H01P 3/08

(52) U.S. Cl. CPC H05K 1/0203; H01P 3/081; H05K 1/0243; H05K 1/181

(57) ABSTRACT

A high-frequency circuit of embodiments includes a dielectric substrate, a signal line, a circuit element, and an array of heat conductive patterns. The signal line is formed on at least one surface of the dielectric substrate, and transmits a high-frequency signal. The circuit element is formed on the at least one surface or both surfaces of the dielectric substrate. The array of heat conductive patterns is formed on the at least one surface of the dielectric substrate. The array of heat conductive patterns can generally release heat from the dielectric substrate. In addition, the array of heat conductive patterns has a resonant frequency equal to or greater than a frequency of a signal transmitted through the signal line.

### CROSS-REFERENCE TO RELATED APPLICATION

This application is based upon and claims the benefit of priority from Japanese Patent Application No. 2017-053117, filed Mar. 17, 2017; the entire contents of which are incorporated herein by reference.

### FIELD

Embodiments described herein relate generally to a high-frequency circuit.

### BACKGROUND

In the related art, a wireless or wired communication apparatus has a high frequency circuit for wireless or wired communication. The high frequency circuit may include an amplifier, a mixer, a filter, and a phase shifter. If the high frequency circuit is defined to operate at low temperature, then it is necessary to keep circuit elements at low temperature by avoiding the circuit elements to be heated up through heat change to high temperature environment. Avoiding the circuit elements to be heated up can, for example, be achieved by thermally shielding the circuit elements from outside heat. The high frequency circuit may generally have a substrate of a dielectric material that has relatively low heat conductivity, which makes it difficult to cause heat release from the high frequency circuit through the substrate. Thus, this dielectric substrate makes it difficult to keep the circuit elements of the high frequency circuit at low temperature and cause the high frequency circuit to exhibit designed high performance.

### BRIEF DESCRIPTION OF THE DRAWINGS

FIG. 1 is a diagram which describes a configuration of a high-frequency processing apparatus 10.

FIG. 2 is a diagram which shows a portion of the high-frequency circuit 100 of a first embodiment.

FIG. 3 is a diagram which shows a relationship between an electrical length of heat conductive pattern 130 and a transmission loss of a signal line 120.

FIG. 4 is a diagram which shows a portion of a high-frequency circuit 100A of a second embodiment.

FIG. 5 is a diagram which shows a relationship between amplitude characteristics of signal lines 122 and 124 and a coupled resonator 150 according to a change in frequency.

FIG. 6 is a diagram which shows a relationship between phase characteristics of the signal lines 122 and 124 and the coupled resonator 150 according to the change in frequency.

FIG. 7 is a diagram which shows an example of isolation between signal lines in the high-frequency circuit 100A of the second embodiment.

FIG. 8 is a diagram which shows a portion of a high-frequency circuit 100B according to a third embodiment.

FIG. 9 is a diagram which shows a portion of a high-frequency circuit 100C according to a fourth embodiment.

### DETAILED DESCRIPTION

An object of the present invention is to provide a high-frequency circuit capable of suppressing a temperature rise of a high-frequency circuit which has been cooled down.

A high-frequency circuit of embodiments includes a dielectric substrate, signal lines, circuit elements, and an array of heat conductive patterns. The signal line is formed on at least one surface of the dielectric substrate, and transmits a high-frequency signal. The circuit element is formed on the at least one surface or both surfaces of the dielectric substrate. The array of heat conductive patterns is formed on the at least one surface of the dielectric substrate. The array of heat conductive patterns can generally release heat from the dielectric substrate. In addition, the array of heat conductive patterns has a resonant frequency equal to or greater than a frequency of a signal transmitted through the signal line.

Hereinafter, a high-frequency circuit of embodiments will be described with reference to drawings. The term “conductive” or “conductivity” used here refers to “heat-conductive” or “heat-conductivity”.

### First Embodiment

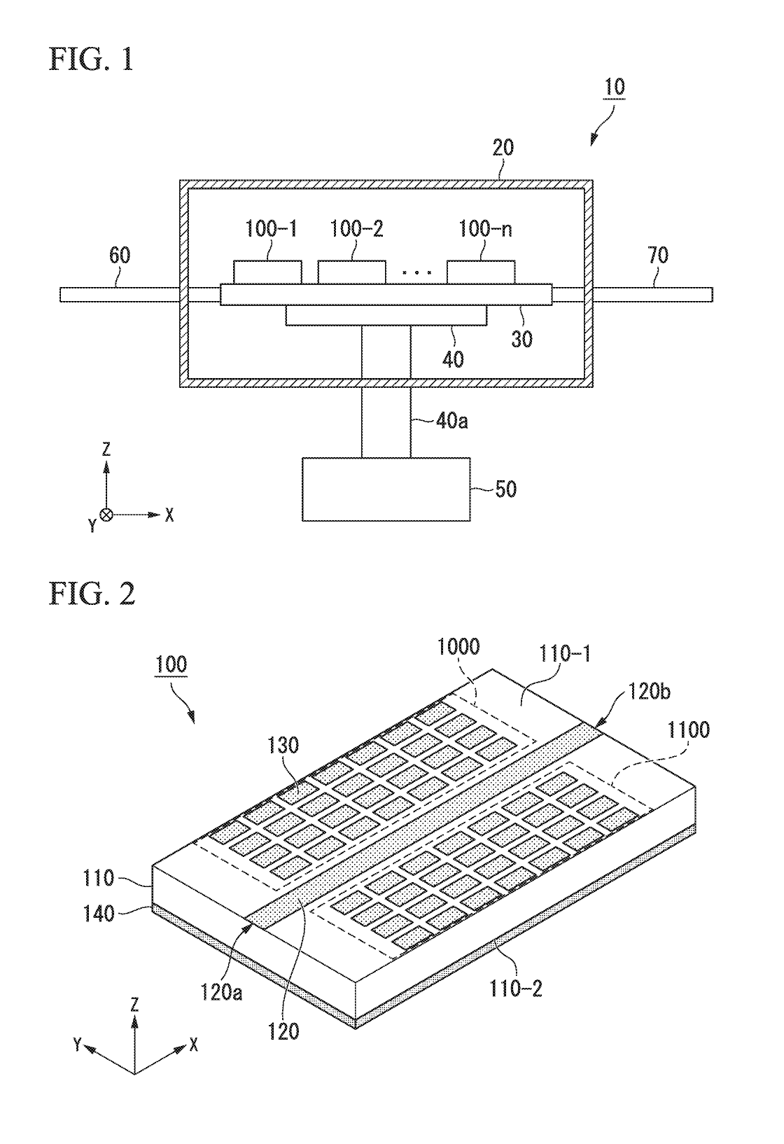

First, a high-frequency processing apparatus accommodating a high-frequency circuit of a first embodiment will be described. FIG. 1 is a diagram which describes a configuration of a high-frequency processing apparatus 10. The high-frequency processing apparatus 10 includes, for example, a vacuum airtight container 20, a base plate 30, a cold head (cooling end) 40, a connecting portion 40a, a compressor 50, and a plurality of high-frequency circuits 100-1 to 100-n (n is a natural number of two or more). Hereinafter, when a high-frequency circuit is not distinguished, the high-frequency circuits are collectively referred to as “high-frequency circuit 100”. In addition, the cold head (cooling end) 40, the connecting portion 40a, and the compressor 50 are portions in a configuration of a cooling device. Other components of the cooling device may be included in the high-frequency processing apparatus 10.

The vacuum airtight container 20 keeps the inside thereof in a low-pressure state with a high insulation effect, for example, by exhausting air using a pump which is not illustrated. The vacuum airtight container 20 is formed of a metal material such as stainless steel.

The high-frequency circuit 100 is mounted on a first surface (upper surface) of the base plate 30. In addition, the base plate 30 is connected to the cold head 40 cooled by the compressor 50 on a second surface (lower surface) thereof which is opposite to the first surface. In addition, the base plate 30 has a fixed input cable 60 for inputting a signal to the high-frequency circuit 100 and a fixed output cable 70 for outputting a signal. An input signal supplied via the input cable 60 is supplied to the high-frequency circuit 100. Moreover, a signal output by the high-frequency circuit 100 is output to the output cable 70.

The cold head 40 is connected to the compressor 50 outside the airtight container 20 by the connecting portion 40a. The connecting portion 40a passes through a wall of the vacuum airtight container 20 while maintaining airtightness. The cold head 40 radiates heat of the high-frequency circuit 100 to the compressor 50 side via the base plate 30.

The compressor 50 compresses, for example, a gaseous refrigerant (refrigerant gas), and cools the cold head 40 to a predetermined temperature using the compressed refrigerant or the like. The input cable 60 supplies a signal from the outside to the high-frequency processing apparatus 10. The output cable 70 outputs the signal supplied by the high-frequency processing apparatus 10 to the outside.

The high-frequency circuit 100 is mounted on the first surface of the base plate 30. The high-frequency circuit 100 performs processes such as amplification, synthesis, filtering, and distribution of the input high-frequency signal. The high-frequency circuit 100 includes, for example, an amplifier, a mixer, a filter, a distribution circuit, a phase shift circuit, and the like. A specific configuration of the high-frequency circuit 100 will be described below.

For example, the high-frequency processing apparatus 10 cools the cold head 40 using the compressor 50 until the high-frequency circuit 100 reaches a low temperature (for example, 150 [K] or below) via the base plate 30. As a result, the high-frequency circuit 100 is brought into a low temperature state, and thus, for example, when a superconducting material is used for a circuit member, the high-frequency circuit is brought into a superconducting state, and can realize a signal process with high accuracy and reduced thermal noises.

Next, the configuration of the high-frequency circuit 100 will be described. FIG. 2 is a diagram which shows a portion of the high-frequency circuit 100 of the first embodiment. A portion of the high-frequency circuit 100 is provided with, for example, a dielectric substrate 110, a signal line 120, a heat conductive pattern 130, and a ground conductor 140.

The dielectric substrate 110 has a first surface 110-1 and a second surface 110-2. The second surface 110-2 has the ground conductor 140. The first surface 110-1 has a first area 1000 and a second area 1100.

The first surface 110-1 has a signal line 120. The signal line 120 separates the first area 1000 and the second area 1100. The signal line 120 may extend on a longitudinal center axis of the first surface 110-1 between opposite short sides of the first surface 110-1. The signal line 120 has a first end 120a and a second end 120b which are on the opposite short sides of the first surface 110-1.

The first area 1000 has a first matrix array of heat conductive patterns 130. The first matrix array of heat conductive patterns 130 may be, but is not limited to, 4×7 of heat conductive patterns 130. The second area 1100 has a second matrix array of heat conductive patterns 130. The second matrix array of heat conductive patterns 130 may be, but is not limited to, 4×7 of heat conductive patterns 130. The first matrix and the second matrix may be, but is not limited to, the same in layout as each other.

The dielectric substrate 110 is a substrate formed of a ceramic material such as alumina which is a dielectric material with low loss in a high-frequency band or a substrate formed of a single crystal such as Sapphire or magnesium oxide. The signal line 120 which transmits a high-frequency signal is formed on a first surface (upper surface) of the dielectric substrate 110.

The signal line 120 is, for example, a microstrip line. The signal line 120 outputs a high-frequency signal input to a signal input terminal 120a from the signal output terminal 120b. The array of heat conductive patterns being configured to release heat from the dielectric substrate. The heat conductive pattern 130 suppresses a radiant heat occurring in, for example, the dielectric substrate 110. The array heat conductive patterns 130 are metal electrodes including conductors with low emissivity such as gold, silver, and copper. At least one suppression member 130 is disposed at a position not in contact with the signal line 120 on a portion in which an upper substrate of the dielectric substrate 110 is exposed.

In addition, the heat conductive pattern 130 disposed at intervals so that the heat conductive patterns 130 are not in contact with each other. Moreover, the heat conductive pattern 130 are disposed such that, for example, an area covering the dielectric substrate 110 is equal to or larger than 30% of an exposed area of the original dielectric substrate 110. It is preferable to install multiple heat conductive patterns 130 to reduce the exposed area of the dielectric substrate 110.

The ground conductor 140 is formed on a second surface (lower surface) of the dielectric substrate 110. The array of heat conductive patterns 130 are grounded by being connected to the ground conductor 140 using a through hole or the like. Accordingly, it is possible to dispose a ground pattern which has no influence on high-frequency characteristics around the signal line 120 formed on the dielectric substrate 110.

If the heat conductive patterns 130 corresponding to the ground are disposed on the dielectric substrate 110 having a circuit configuration in which a through-hole process is hardly performed, the heat conductive patterns 130 may resonate themselves and affect the surrounding high-frequency circuit 100.

When the dielectric substrate 110 has a circuit configuration in which a through-hole process is hardly performed, or when the dielectric substrate 110 has a circuit configuration in which the through-hole process can be performed, the heat conductive pattern 130 is preferably set so that a resonance frequency is equal to or greater than a frequency of the signal transmitted through the signal line 120, more preferably, a resonance frequency of the lowest order is equal to or greater than the frequency of the signal transmitted through the signal line 120.

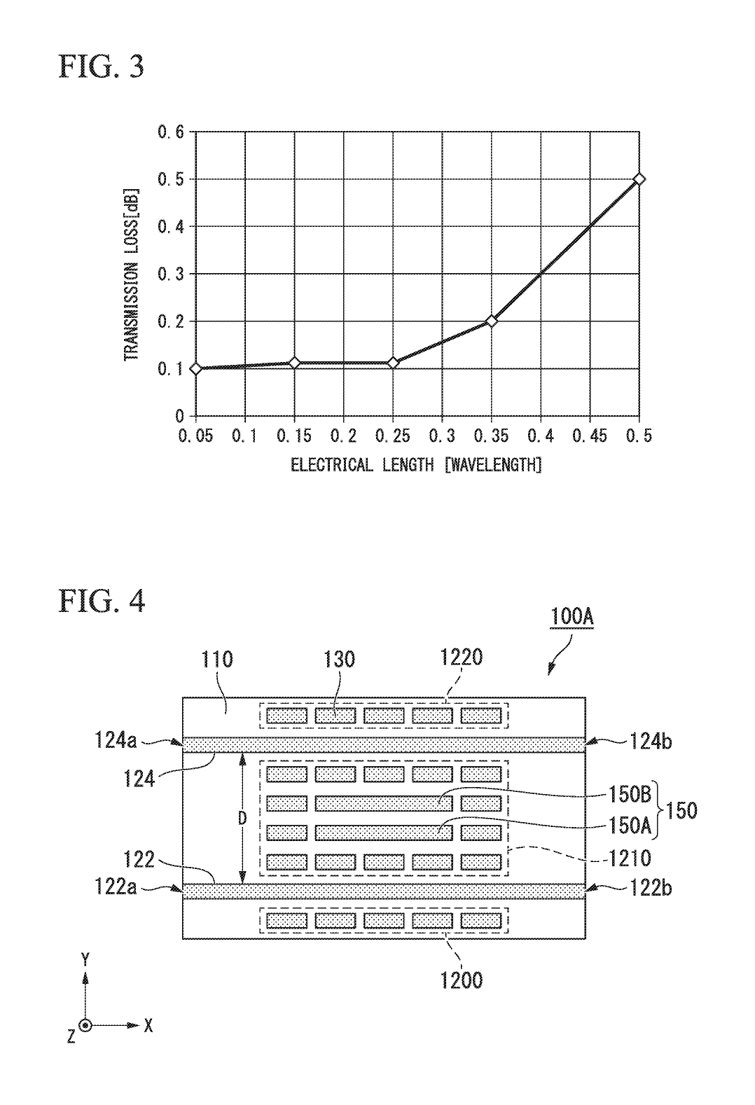

In addition, an electrical length of the heat conductive pattern 130 may be set within a range that does not affect the high-frequency circuit 100. FIG. 3 is a diagram which shows a relationship between an electrical length of the heat conductive pattern 130 and a transmission loss of the signal line 120. The horizontal axis of FIG. 3 represents the electrical length [wavelength] of the heat conductive pattern 130, and the vertical axis thereof represents the transmission loss [dB] of the signal line 120. FIG. 3 shows a relationship between the electrical length of the heat conductive pattern 130 and the transmission loss of the signal line 120 when, for example, a microstrip line using an alumina substrate having a thickness of 0.5 [mm] and a dielectric constant of 9.6 is defined as the signal line 120 and a signal of a frequency 5 GHz is transmitted to the signal line 120.

According to the relationship shown in FIG. 3, for example, when the electrical length of the heat conductive pattern 130 is in a vicinity of 0.5 [wavelength] (λ/2), the transmission loss is about 0.5 [dB]. This transmission loss occurs due to resonance of the heat conductive pattern 130 itself in a vicinity of a signal passing through the signal line 120. The transmission loss may be about 0.5 [dB] or less. In this case, the electrical length of the heat conductive pattern 130 is preferably ½ or less of a wavelength of the signal transmitted through the signal line 120.

In addition, the transmission loss also decreases if the electrical length of the heat conductive pattern 130 is reduced from 0.5 [wavelength], and when the electrical length of the heat conductive pattern 130 is set to be ¼ [wavelength] (74) or less, the transmission loss is suppressed to be stably about 0.1 [dB]. Therefore, the electrical length of the heat conductive pattern 130 is more preferably set to be ¼ or less of the wavelength of the signal transmitted through the signal line 120. In this case, a wavelength of a signal transmitted by the heat conductive pattern 130 is ¼ or less of the wavelength of the signal transmitted through the signal line 120.

Moreover, the heat conductive pattern 130 is in a shape such as a triangle, a rectangle, a regular polygon, a circle, an ellipse, a rhombus, or a star, or a combination of a plurality of different shapes. These shapes may be set according to, for example, a shape of the dielectric substrate 110, a wiring pattern of the signal line 120, a shape of an exposed area of the dielectric, or the like. In addition, the dielectric substrate 110 may also be provided with various types of circuit elements such as an amplifier, a mixer, a filter, a distribution circuit, and a phase shift circuit in addition to the configurations described above.

As described above, according to the high-frequency circuit 100 of the first embodiment, it is possible to suppress the radiant heat occurring in the dielectric substrate 110 and to suppress a heat transfer to a circuit portion from the dielectric substrate 110. As a result, penetration of heat can be reduced without deteriorating high-frequency characteristics. Therefore, for example, when the high-frequency circuit 100 is cooled down to be in a superconducting state, an increase in heat is suppressed and it is possible to stably maintain the superconducting state.

### Second Embodiment

Next, a configuration of a high-frequency circuit according to a second embodiment will be described. When compared with the high-frequency circuit 100 of the first embodiment, a high-frequency circuit 100A of the second embodiment is different in that the high-frequency circuit 100A includes a first signal line 122, a second signal line 124, and a coupled resonator 150. Therefore, components of the first signal line 122, the second signal line 124, and the coupled resonator 150 will be mainly described in the following description. In addition, the same names and reference numerals will be used for components having the same function as in the high-frequency circuit 100 of the first embodiment and detailed description will be omitted in the following description.

FIG. 4 is a diagram which shows a portion of the high-frequency circuit 100A of the second embodiment.

The high-frequency circuit 100A has a first area 1200, a second area 1210, and a third area 1220. The high-frequency circuit 100A has a first signal line 122 and a second signal line 124. The first signal line 122 separates the first area 1200 and the second area 1210. The second signal line 124 separates the second area 1210 and the third area 1220.

The first area 1200 has a first matrix array of heat conductive patterns 130. The first matrix array of heat conductive patterns 130 may be, but is not limited to, 1×5 of heat conductive patterns 130.

The second area 1210 has a second matrix array of heat conductive patterns 130 and a coupled resonator 150.

The third area 1220 has a third matrix array of heat conductive patterns 130. The third matrix array of heat conductive patterns 130 may be, but is not limited to, 1×5 of heat conductive patterns 130.

The high-frequency circuit 100A includes the first signal line 122 and the second signal line 124 disposed in parallel on the dielectric substrate 110. The first signal line 122 and the second signal line 124 are, for example, microstrip lines. The first signal line 122 outputs a high-frequency signal input from the signal input terminal 122a from the signal output terminal 122b. The second signal line 124 outputs a signal input from the signal input terminal 124a from the signal output terminal 124b.

For example, when these two signal lines are disposed in parallel, a magnetic field is generated by a current flowing in one signal line and isolation (signal leakage) between the signal lines is generated by magnetic field coupling with the other signal line, and thereby characteristics are likely to deteriorate. Therefore, the coupled resonator 150 is disposed between the first signal line 122 and the second signal line 124 in the high-frequency circuit 100A. The coupled resonator 150 is disposed when, for example, a distance D between the first signal line 122 and the second signal line 124 is equal to or less than a threshold value. The coupled resonator 150 includes a pair of conductive line segment.

Each of the heat conductive patterns 130 has a dimension in the direction parallel to the first signal line 122 and the second signal line 124. The dimension depends on the electrical length of each of the first signal line 122 and the second signal line 124. The dimension of the heat conductive patterns 130 is shorter than the length which will course a resonance at a frequency of a high frequency signal which is propagating on the first signal line 122 and the second signal line 124.

The coupled resonator 150 includes, for example, two resonators 150A and 150B which resonate at a predetermined frequency (for example, 9 [GHz]). The resonators 150A and 150B are, for example, disposed in parallel with each other, and are also parallel with the first signal line 122 and the second signal line 124.

A coupled resonator 150 has a dimension in the direction parallel to the first signal line 122 and the second signal line 124. The dimension depends on the electrical length of each of the first signal line 122 and the second signal line 124. The dimension of the coupled resonator 150 has the length which will course a resonance at a frequency of a high frequency signal which is propagating on the first signal line 122 and the second signal line 124.

In addition, the resonators 150A and 150B are formed of; for example, a resonance element. Moreover, the resonators 150A and 150B may be formed by electrically connecting a plurality of heat conductive patterns 130, respectively. As a result, the first signal line 122 and the second signal line 124 are directly coupled by a magnetic field, and the coupled resonator 150 therebetween couples the resonators 150A and 150B. Furthermore, a magnetic field of the resonator 150A is coupled with a magnetic field of the first signal line 122, and a magnetic field of the resonator 150B is coupled with a magnetic field of the second signal line 124.

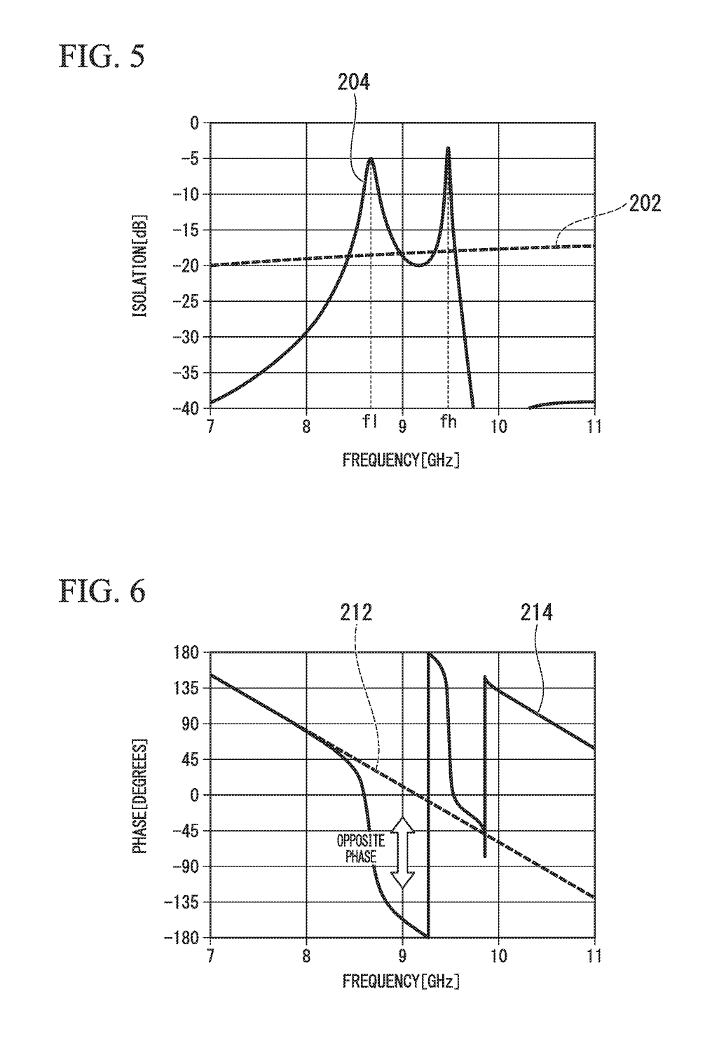

Here, a relationship between amplitude characteristics and phase characteristics of the first signal line 122, the second signal line 124, and the coupled resonator 150 will be described. FIG. 5 is a diagram which shows a relationship between the amplitude characteristics of the signal lines 122 and 124 and the coupled resonator 150 according to a change in frequency. The horizontal axis of FIG. 5 represents a frequency [GHz], and the vertical axis thereof represents isolation [dB]. For example, the resonators 150A and 150B have electrical lengths of 0.5 [wavelength] and resonate at about 9 [GHz]. In this case, the relationship between amplitude characteristics appears as shown in FIG. 5. FIG. 5 shows an isolation result 202 of the amplitude characteristics when the first signal line 122 and the second signal line 124 are directly coupled and an isolation result 204 of the amplitude characteristics of a high-frequency signal output from a second signal output unit (for example, the signal output terminal 124b) via the coupled resonator 150 from the first signal line input unit (for example, the signal input terminal 122a). According to the relationship shown in FIG. 5, a peak of the amplitude characteristics is split into two, a frequency fl and a frequency fh, by the coupled resonator 150.

In addition, FIG. 6 is a diagram which shows a relationship between the phase characteristics of the signal lines 122 and 124 and the coupled resonator 150 according to a change in frequency. The horizontal axis of FIG. 6 represents a frequency [GHz], and the vertical axis thereof represents phase shift [degrees]. For example, when the resonators 150A and 150B having a length of 0.5 [wavelength] and resonating at 9 [GHz] are coupled, a relationship between the phase characteristics appears as shown in FIG. 6. FIG. 6 shows a result 212 of the phase characteristics in the first signal line 122 and the second signal line 124, and a result 214 of the phase characteristics via the coupled resonator 150. According to the relationship shown in FIG. 6, a phase is inverted before and after the resonance peak is split into two. Therefore, a coupling coefficient of the coupled resonator 150 is set so that the isolation in the first signal line 122 and the second signal line 124 is equal to the amplitude characteristics in the vicinity of a center frequency (for example, a lowest order resonance frequency) of the coupled resonator 150 in amount, and thereby it is possible to cancel out or to weaken the two magnetic fields in opposite phases.

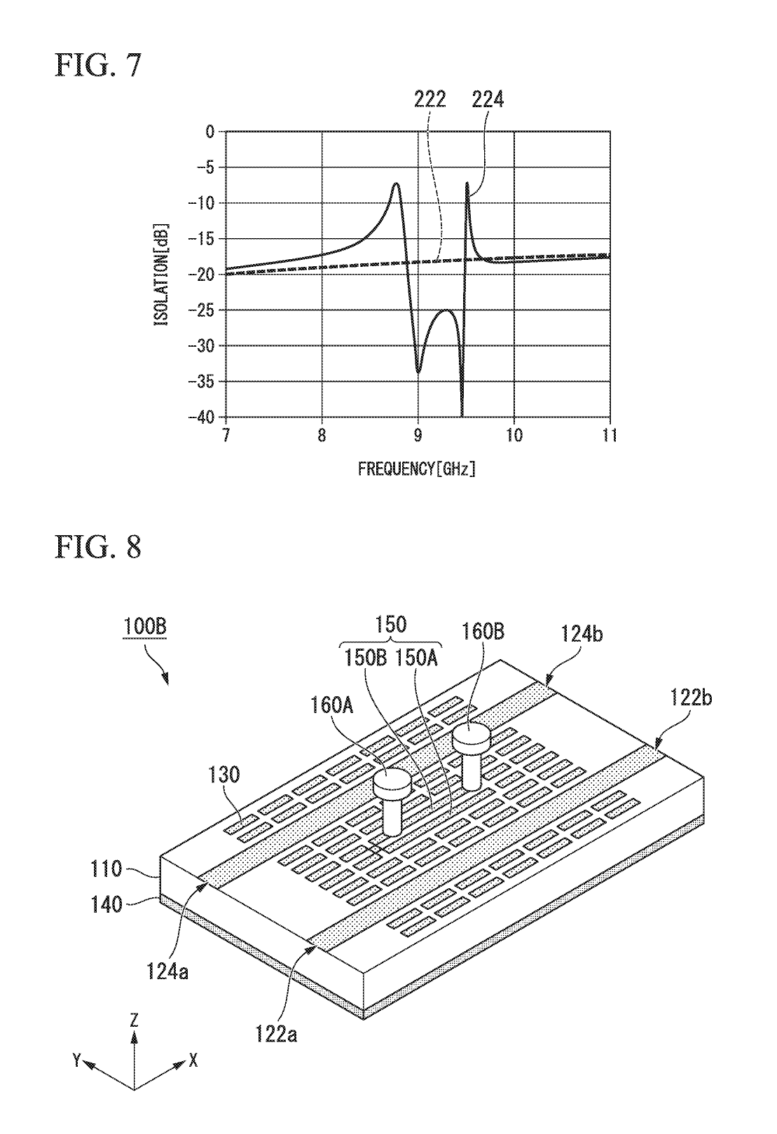

FIG. 7 is a diagram which shows an example of the isolation between signal lines in the high-frequency circuit 100A of the second embodiment. The horizontal axis of FIG. 7 represents a frequency [GHz], and the vertical axis thereof represents isolation characteristics [dB]. In an example of FIG. 7, isolation characteristics reflecting a result of the amplitude characteristics shown in FIG. 5 and the phase characteristics shown in FIG. 6 are shown. FIG. 7 shows an isolation result 222 of the first signal line 122 and the second signal line 124 which do not include the coupled resonator 150 and an isolation result 244 of the first signal line 122 and the second signal line 124 which include the coupled resonator 150.

As shown in FIG. 7, it is known that isolation of the first signal line 122 and the second signal line 124 which include the coupled resonator 150 is increased compared to that of a case not including the coupled resonator 150 by about 10 [dB] or more in the vicinity of the center frequency (9 [GHz]) of the coupled resonator 150. Therefore, when a physical quantity generated by an electromagnetic coupling between the first signal line 122 and the second signal line 124 is equal to a physical quantity of a high-frequency signal generated via the coupled resonator 150 at the lowest order resonance frequency of the coupled resonator 150, a canceling out effect due to the phase inversion becomes large. The physical quantity is, for example, an electromagnetic coupling amount generated by electromagnetic coupling.

As described above, according to the high-frequency circuit 100A of the second embodiment, it is possible to improve isolation between signal lines or elements in addition to there being the same effect as in the first embodiment. In addition, the first signal line 122 and the second signal line 124 do not need to be separated from each other so that the influence of the magnetic field does not occur therebetween, and thus it is possible to decrease the high-frequency circuit 100A in size.

### Third Embodiment

Next, a configuration of a high-frequency circuit according to a third embodiment will be described. A high-frequency circuit 100B of the third embodiment is different from the high-frequency circuit 100A of the second embodiment in that the high-frequency circuit 100B includes a dielectric member 160. Therefore, in a following description, a configuration of the dielectric member 160 will be mainly described. In addition, components having the same functions as in the high-frequency circuit 100A of the second embodiment will be given the same names and reference numerals, and detailed description thereof will be omitted in the following description.

FIG. 8 is a diagram which shows a portion of the high-frequency circuit 100B according to the third embodiment. For example, the high-frequency circuit 100B has an arrangement layout as shown in FIG. 8.

The high-frequency circuit 100B includes two dielectric members 160A and 160B for adjusting an electromagnetic coupling amount or a frequency between the resonators 150A and 150B.

The two dielectric members 160A and 160B are formed in, for example, a rod shape and mounted on the coupled resonator 150. It is possible to adjust at least one of the electromagnetic coupling amounts and the resonance frequency of the coupled resonator 150 by increasing or decreasing a distance between the two dielectric members 160A and 160B. For example, the two dielectric members 160A and 160B are arranged at a position above the coupled resonator 150 to adjust a coupling amount or a resonance frequency of the coupled resonator 150 so as to obtain the most canceling out effect with respect to the electromagnetic coupling amount generated by electromagnetic coupling between the first signal line 122 and the second signal line 124 and electromagnetic coupling amount generated by the coupled resonator 150.

Here, as a material of the dielectric members 160A and 160B, for example, a dielectric material having characteristics of low loss at a high-frequency is preferable and sapphire or alumina is used. In addition, shapes of the dielectric members 160A and 160B may be, for example, a rectangular column or a substrate shape. Moreover, since the dielectric member 160A is disposed on the upper surface of a dielectric substrate, the dielectric member 160A is installed on a cover to cover a portion of the high-frequency circuit 100B, and the dielectric member 160A and the high-frequency circuit 100B may be disposed while a fixed interval there between is maintained.

As described above, according to the high-frequency circuit 100B of the third embodiment, in addition to there being the same effect as in the first and the second embodiments, it is possible to further improve isolation between signal lines or elements by installing the dielectric members 160A and 160B at a position at which the most canceling out effect is obtained with respect to a physical quantity of a high-frequency signal generated by electromagnetic coupling between the first signal line 122 and the second signal line 124 and a physical quantity of a high-frequency signal generated by the coupled resonator 150.

### Fourth Embodiment

Next, a configuration of a high-frequency circuit according to a fourth embodiment will be described. A high-frequency circuit 100C of the fourth embodiment is different from the high-frequency circuit 100A of the second embodiment in that the high-frequency circuit 100C includes a distribution circuit 170 as an example of a circuit element. As a result, a configuration of the distribution circuit 170 will be mainly described in the following description. In addition, a configuration including the same function as the high-frequency circuit 100A of the second embodiment will be given the same name and reference numeral, and detailed description will be omitted in the following description.

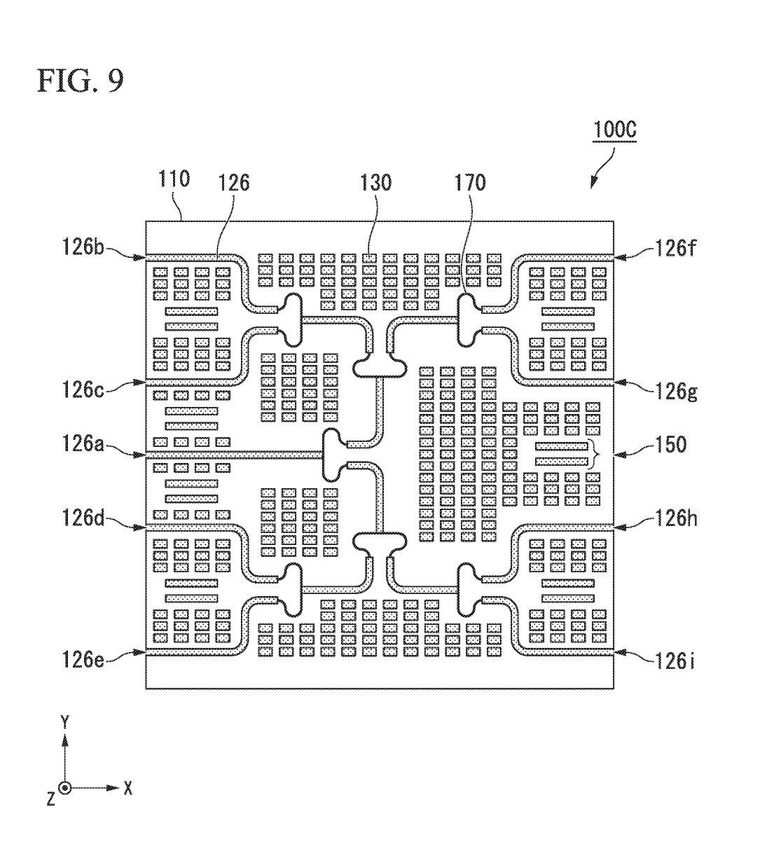

FIG. 9 is a diagram which shows a portion of the high-frequency circuit 100C according to the fourth embodiment. For example, the high-frequency circuit 100C has an arrangement layout as shown in FIG. 9.

The high-frequency circuit 100C includes, for example, a signal line 126, a heat conductive pattern 130, a coupled resonator 150, and a distribution circuit 170 on the dielectric substrate 110.

The distribution circuit 170, for example, distributes a signal input from one signal line to two signal lines and outputs the signal. Although not illustrated, the distribution circuit 170 may connect an absorption resistance between the distributed lines and may configure a Wilkinson power divider circuit.

The signal line 126 is, for example, a microstrip line. In an example of FIG. 9, a high-frequency signal input from a signal input terminal 126a is divided into eight via a plurality of power divider circuits 170, and is output from signal output terminals 126b to 126i of respective signal lines 126. In addition, a plurality of heat conductive patterns 130 are disposed between the signal lines 126 at predetermined intervals. Moreover, the coupled resonator 150 is disposed between the signal lines 126.

As described above, according to the high-frequency circuit 100C of the fourth embodiment, it is possible to improve isolation between lines using the heat conductive pattern 130 and the coupled resonator 150 in addition to there being the same effect as in the first and the second embodiments, and thus it is possible to ameliorate imbalance of a power ratio in the power divider circuit 170.

Each of the first to the fourth embodiments may be combined with some or all of the other embodiments. The high-frequency circuits 100, 100A, 100B, and 100C described above may include a signal line or a circuit element on the lower surface instead of or in addition to the upper surface of the dielectric substrate 110. Moreover, suppression pads having a plurality of heat conductive patterns 130 arranged with predetermined gaps therebetween may be mounted on the dielectric substrate 110. In this case, the suppression pads are arranged so that, for example, a size of the heat conductive pattern 130 is equal to a size of the gap.

According to at least one of the embodiments described above, the high-frequency circuit 100 includes the dielectric substrate 110, the signal line 120 which is formed on one surface or both surfaces of the dielectric substrate 110 and transmits a high-frequency signal, a circuit element which is formed on one surface or both surfaces of the dielectric substrate 110, and a heat conductive pattern 130 which suppresses radiant heat to the dielectric substrate 110, and it is possible to suppress a temperature rise by setting a resonance frequency of the heat conductive pattern 130 to be equal to or greater than a frequency of a signal transmitted through the signal line 120.

Several embodiments of the present invention have been described, but these embodiments are presented as examples and are not intended to limit the scope of the invention. These embodiments can be implemented in various other forms, and various omissions, substitutions, and changes can be made within a range not departing the gist of the invention. These embodiments and modifications thereof are included in the invention described in the claims and the scope of equivalents thereof as well as in the scope and the gist of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A high-frequency circuit comprising:
a dielectric substrate;
a signal line formed on at least one surface of the dielectric substrate and transmitting a high frequency signal;
a circuit element formed on the at least one surface of the dielectric substrate; and
an array of heat conductive patterns on the at least one surface of the dielectric substrate, the array of heat conductive patterns being configured to release heat from the dielectric substrate,
wherein the array of heat conductive patterns has a resonant frequency equal to or greater than a frequency of a signal transmitted through the signal line.

2. The high-frequency circuit according to claim 1,
wherein an electrical length of the heat conductive pattern is set to be equal to or less than ½ of a wavelength of the signal transmitted through the signal line.

3. The high-frequency circuit according to claim 1,
wherein a coupled resonator configured to electromagnetically couple two resonators having ½ of the wavelength of the signal transmitted through a first signal line and a second signal line is disposed between the first signal line and the second signal line formed in parallel on the dielectric substrate.

4. The high-frequency circuit according to claim 3,
wherein a physical quantity of a high-frequency signal generated in the coupled resonator is equal to a physical quantity of a high-frequency signal generated by electromagnetic coupling between the first signal line and the second signal line at a lowest order resonance frequency of the coupled resonator.

5. The high-frequency circuit according to claim 3,
a dielectric member configured to adjust at least one of an electromagnetic coupling amount or a frequency of the coupled resonator.

6. The high-frequency circuit according to claim 1,
wherein a wavelength of the signal transmitted through the heat conductive pattern is equal or less than ¼ of the wavelength of the signal transmitted through the signal line.
